(19) United States
(12) Patent Application Publication
(10) Pub. No.: US 2025/0062233 A1
(43) Pub. Date: Feb. 20, 2025

(54) SEMICONDUCTOR DEVICE AND MANUFACTURING METHOD OF THE SEMICONDUCTOR DEVICE

(71) Applicant: SK hynix Inc., Icheon (KR)

(72) Inventors: So Young YIM, Icheon (KR); Jeong Soo KIM, Icheon (KR); Geun Hyeok JANG, Icheon (KR)

(21) Appl. No.: 18/584,933

(22) Filed: Feb. 22, 2024

(30) Foreign Application Priority Data
Aug. 18, 2023 (KR) 10-2023-0108164

(51) Int. Cl. H01L 23/532; H01L 21/02; H01L 21/768; H10B 63/10

(52) U.S. Cl. CPC H01L 23/532; H01L 21/0228; H01L 21/76831; H01L 21/76856; H10B 63/10

(57) ABSTRACT

A semiconductor device may include: a first conductive line extending in a first direction; a second conductive line extending in a second direction intersecting the first direction; a memory cell located between the first conductive line and the second conductive line in a third direction that is intersecting to the first and second directions; and a liner pattern located over a sidewall of the memory cell and including a first portion and a second portion, the first portion including halide impurities at a first concentration, the second portion including halide impurities at a second concentration that is lower than the first concentration.

### CROSS-REFERENCE TO RELATED APPLICATION

This application claims priority under 35 U.S.C. § 119 to Korean Patent Application No. 10-2023-0108164 filed on Aug. 18, 2023, which is incorporated herein by reference in its entirety.

### BACKGROUND

### 1. Technical Field

Embodiments of the present disclosure relate to an electronic device and a manufacturing method of the electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a first conductive line extending in a first direction; a second conductive line extending in a second direction intersecting the first direction; a memory cell located between the first conductive line and the second conductive line in a third direction that is intersecting to the first and second directions; and a liner pattern located over a sidewall of the memory cell and including a first portion and a second portion, the first portion including halide impurities at a first concentration, the second portion including halide impurities at a second concentration that is lower than the first concentration.

In an embodiment, a manufacturing method of a semiconductor device may include: forming a variable resistance layer; forming a buffer layer on a sidewall of the variable resistance layer; and forming a liner layer on the buffer layer, the liner layer including a first portion and a second portion, the first portion including halide impurities at a first concentration, the second portion including halide impurities at a second concentration that is lower than the first concentration.

### BRIEF DESCRIPTION OF THE DRAWINGS

FIGS. 1A and 1B illustrate a semiconductor device in accordance with an embodiment.

FIGS. 2A to 2C illustrate a semiconductor device in accordance with an embodiment.

FIGS. 3A to 3D illustrate a manufacturing method of a semiconductor device in accordance with an embodiment.

FIGS. 4A, 5A, 6A, 7A, 8A, and 9A are plan views illustrating a manufacturing method of a semiconductor device in accordance with an embodiment.

FIGS. 4B, 5B, 6B, 7B, 8B, and 9B are cross-sectional views illustrating the manufacturing method of the semiconductor device shown in FIGS. 4A, 5A, 6A, 7A, 8A, and 9A, respectively.

FIGS. 10A and 10B illustrate an effect of a manufacturing method of a semiconductor device in accordance with an embodiment.

FIGS. 11A and 11B illustrate an effect of a manufacturing method of a semiconductor device in accordance with an embodiment.

### DETAILED DESCRIPTION

Various embodiments of the present disclosure are directed to a semiconductor device having a stable structure and improved characteristics and a manufacturing method of the semiconductor device.

According to the present technology, it is possible to provide a semiconductor device having a stable structure and improved reliability.

Hereafter, embodiments in accordance with the technical spirit of the present disclosure will be described with reference to the accompanying drawings.

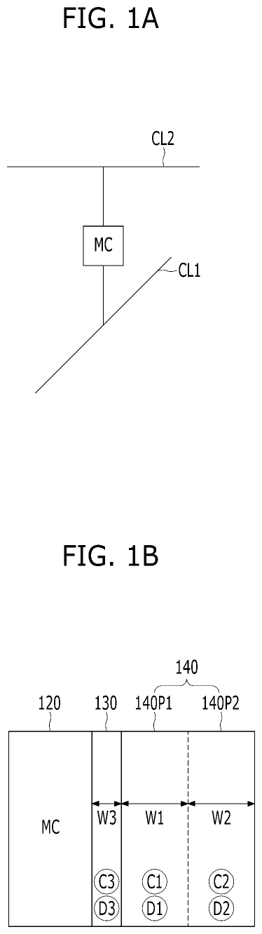

FIGS. 1A and 1B illustrate a semiconductor device in accordance with an embodiment.

Referring to FIG. 1A, the semiconductor device may include at least one of a first conductive line CL1, a second conductive line CL2, or a memory cell MC. The memory cell MC may be located between the first conductive line CL1 and the second conductive line CL2. Here, the first conductive line CL1 may extend in a first direction, and the second conductive line CL2 may extend in a second direction intersecting the first direction. Each of the first conductive line CL1 and the second conductive line CL2 may be a word line, a bit line, a select line, or the like. For example, when the first conductive line CL1 is a word line, the second conductive line CL2 may be a bit line.

Alternatively, when the first conductive line CL1 is a bit line, and the second conductive line CL2 may be a word line.

The memory cell MC may include a variable resistance layer. The variable resistance layer may include a chalcogenide material. The semiconductor device may be a phase change random access memory (PRAM) device, a magnetic random access memory (MRAM) device, a self-selecting memory device, a resistive random access memory (RRAM) device, or the like.

Referring to FIG. 1B, the semiconductor device may include at least one of a memory cell 120, a buffer pattern 130, or a liner pattern 140. The liner pattern 140 may be located on the memory cell 120. In particular, the liner pattern 140 may be located over a sidewall of the memory cell 120. The buffer pattern 130 may be located between the memory cell 120 and the liner pattern 140. At least one of the liner pattern 140 or the buffer pattern 130 may include a nitride layer containing nitride. The liner pattern 140 and the buffer pattern 130 may be used to protect the memory cell 120 in a manufacturing process. For example, the liner pattern 140 and the buffer pattern 130 may encapsulate the memory cell 120 to substantially prevent external impurities from diffusing into the memory cell 120 in the manufacturing process.

The liner pattern 140 may include a first portion 140P1 and a second portion 140P2. The first portion 140P1 is spaced closer to the memory cell 120 than the second portion 140P2 is. For example, the first portion 140P1 may be located between the memory cell 120 and the second portion 140P2. The first portion 140P1 may have a first thickness W1, and the second portion 140P2 may have a second thickness W2. The first thickness W1 and the second thickness W2 may be substantially the same as or different from each other. For example, the first thickness W1 and the second thickness W2 may be substantially the same as each other. The first portion 140P1 may include halide impurities at a first concentration C1. The second portion 140P2 may include halide impurities at a second concentration C2 that is lower than the first concentration C1. Here, the halide impurities may include at least one of iodine (I) or chlorine (Cl).

The first portion 140P1 may have a first density D1, and the second portion 140P2 may have a second density D2. The first density D1 and the second density D2 may be substantially the same as or different from each other. Here, the first density D1 may refer to a density of a nitride layer constituting the first portion 140P1, and the second density D2 may refer to a density of a nitride layer constituting the second portion 140P2.

For example, the second density D2 of the second portion

140P2 may be higher than the first density D1 of the first portion 140P1 because the concentration C2 of the halide impurities in the second portion 140P2 is lower than the concentration C1 of the halide impurities in the first portion 140P1. Here, when the density of the nitride layer of the second portion 140P2 is relatively high, the diffusion of the external impurities into the memory cell 120 may be reduced compared to when the density of the nitride layer of the second portion 140P2 is relatively low.

The buffer pattern 130 may have a third thickness W3 that is smaller than the first thickness W1 and the second thickness W2.

The buffer pattern 130 might not include halide impurities, or may include halide impurities at a third concentration C3. Here, the third concentration C3 may be lower than the first concentration C1 and the second concentration C2.

According to the structure described above with reference to FIGS. 1A and 1B, the second portion 140P2 of the liner pattern 140 may include the halide impurities at the second concentration C2 that is lower than the first concentration C1, and may have the second density D2 that is higher than the first density D1. In addition, the buffer pattern 130 may include the halide impurities at the third concentration C3 that is lower than the first concentration C1 and the second concentration C2. Accordingly, the buffer pattern 130 and the liner pattern 140 may reduce the diffusion of the external impurities into the memory cell 120 in the manufacturing process.

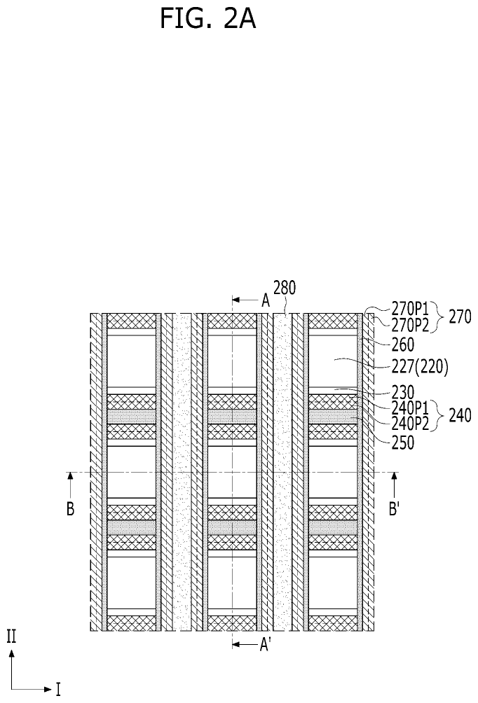

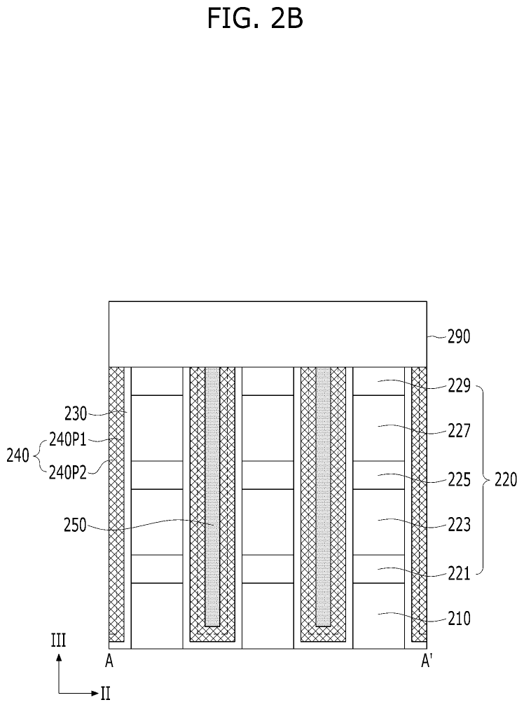

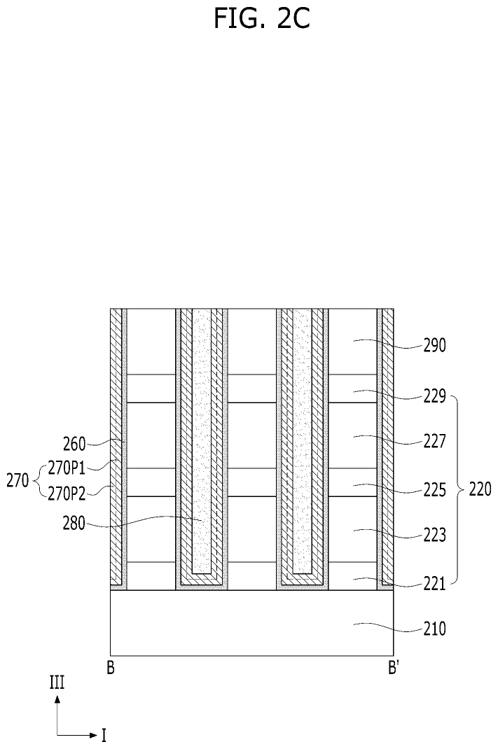

FIGS. 2A to 2C illustrate a semiconductor device in accordance with an embodiment. FIG. 2A is a plan view, FIG. 2B is a cross-sectional view taken along line A-A′ of FIG. 2A, and FIG. 2C is a cross-sectional view taken along line B-B′ of FIG. 2A.

Referring to FIGS. 2A to 2C, the semiconductor device may

include first conductive lines 210, memory cells 220, and second conductive lines 290, or any combination thereof. The semiconductor device may further include at least one of first buffer patterns 230, first liner patterns 240, first gap fill patterns 250, second buffer patterns 260, second liner patterns 270, or second gap fill patterns 280.

The memory cells 220 may be arranged in a first direction I and a second direction II intersecting the first direction I. The memory cell 220 may be located between the first conductive line 210 and the second conductive line 290 in a third direction III that is intersecting to a plane defined by the first direction I and the second direction II. For example, the third direction III may be perpendicular to the first direction I and the second direction II. The memory cell 220 may include a variable resistance pattern 227. The memory cell 220 may further include a first electrode pattern 221, a switching pattern 223, a second electrode pattern 225, a third electrode pattern 229, or any combination thereof.

In the third direction III, the switching pattern 223 may be located on the first electrode pattern 221, and the second electrode pattern 225 may be located on the switching pattern 223. At least one of the first electrode pattern 221, the switching pattern 223, or the second electrode pattern 225 may constitute a selection element. The selection element may be a diode, a positive-negative-positive (PNP) diode, a transistor, a vertical transistor, a bipolar junction transistor (BJT), a metal insulator transition (MIT) element, a mixed ionic-electronic conduction (MIEC) element, an Ovonic threshold switching (OTS) element, or the like.

For example, the switching pattern 223 may include a chalcogenide material. The first electrode pattern 221 may be a lower electrode, and the second electrode pattern 225 may be an intermediate electrode. The third electrode pattern 229 may be located between the variable resistance pattern 227 and the second conductive line 290 in the third direction III. The third electrode pattern 229 may be an upper electrode. The first electrode pattern 221, the second electrode pattern 225, and the third electrode pattern 229 may each include metal, metal nitride, carbon, carbon nitride, or the like.

The variable resistance pattern 227 may be located between the first conductive line 210 and the second conductive line 290 in the third direction III. In particular, the variable resistance pattern 227 may be located on the second electrode pattern 225, and the third electrode pattern 229 may be located on the variable resistance pattern 227. The second electrode pattern 225, the variable resistance pattern 227, and the third electrode pattern 229 may constitute a memory element. The memory element and the selection element may share the second electrode pattern 225 with each other. The variable resistance pattern 227 may include a chalcogenide material.

The first conductive lines 210 may extend in the first direction I. The first conductive lines 210 may be arranged to be spaced apart from each other in the second direction II. The first conductive line 210 may be located below the memory cell 220 and may be electrically connected to the first electrode pattern 221. The first conductive line 210 may be a word line or a bit line. The first conductive line 210 may include a conductive material such as tungsten.

The second conductive lines 290 may extend in the second direction II. The second conductive lines 290 may be arranged to be spaced apart from each other in the first direction I. The second conductive line 290 may be located on the memory cell 220 and may be electrically connected to the third electrode pattern 229. The second conductive line 290 may be a word line or a bit line. For example, when the first conductive line 210 is a word line, the second conductive line 290 may be a bit line. Alternatively, when the first conductive line 210 is a bit line, and the second conductive line 290 may be a word line. The second conductive line 290 may include a conductive material such as tungsten.

The first buffer patterns 230 may extend in the first direction I when viewed in a plan view, and may cover sidewalls of the memory cells 220 in the second direction II. For example, the first buffer patterns 230 may be located on sidewalls of the memory cells 220 that face each other in the second direction II. The first buffer patterns 230 might not be removed in a manufacturing process, and may remain on the sidewalls of the memory cells 220 to protect the memory cells 220. The first buffer patterns 230 may each include an insulating material such as nitride. For example, the first buffer patterns 230 may each include silicon nitride or the like.

The first liner patterns 240 may extend in the first direction I when viewed in a plan view, and may cover the sidewalls of the memory cells 220 in the second direction II. For example, the first liner patterns 240 may be located over the sidewalls of the memory cells 220 that face each other in the second direction II. Each of the first buffer patterns 230 may be located between a corresponding one of the first liner patterns 240 and a corresponding one of the memory cells 220. The first liner patterns 240 might not be removed in the manufacturing process, and may remain over the sidewalls of the memory cells 220 to protect the memory cells 220. The first liner patterns 240 may each include an insulating material such as nitride. For example, the first liner patterns 240 may each include silicon nitride or the like.

The first liner patterns 240 may each include a first portion 240P1 and a second portion 240P2. The first portion 240P1 and the second portion 240P2 may be formed in-situ, or may be formed by separate processes. Accordingly, the first portion 240P1 and the second portion 240P2 may be formed as one layer, or may be formed as separate layers.

In the first liner pattern 240, the first portion 240P1 may have a first thickness, and the second portion 240P2 may have a second thickness. The first thickness and the second thickness may be substantially the same as or different from each other. For example, the first thickness and the second thickness may be substantially the same as each other. The first buffer patterns 230 may each have a third thickness. The third thickness may be substantially the same as or different from the first thickness and the second thickness. For example, the third thickness may be smaller than at least one of the first thickness or the second thickness.

The first portion 240P1 may include halide impurities at a first concentration, and the second portion 240P2 may include halide impurities at a second concentration that is lower than the first concentration. The first buffer patterns 230 may each include halide impurities at a third concentration that is lower than the first concentration and the second concentration. Here, the halide impurities may include at least one of iodine (I) or chlorine (Cl). The first portion 240P1 may have a first density, and the second portion 240P2 may have a second density that is higher than the first density.

In summary, the first buffer pattern 230 might not include the halide impurities, or may include the halide impurities at a lower concentration than the first liner pattern 240. Therefore, the first buffer pattern 230 may have a higher density than the first liner pattern 240. In addition, the concentration of the halide impurities in the second portion 240P2 of the first liner pattern 240 may be lower than that of the halide impurities in the first portion 240P1 of the first liner patterns 240, and thus the density of the second portion 240P2 may be higher than that of the first portion 240P1. Accordingly, the first liner patterns 240 and the first buffer patterns 230 may reduce the diffusion of external impurities into the memory cells 220.

The first gap fill patterns 250 may be located between memory cells 220 arranged in the second direction II. For example, each of the first gap fill patterns 250 may be located between two memory cells 220 adjacent to each other in the second direction II. The first gap fill patterns 250 may be located on the first liner patterns 240 in the second direction II. In a process of forming the first gap fill patterns 250, the first liner patterns 240 may be oxidized. However, since the first liner patterns 240 each include the second portion 240P2 having the high density, they may reduce the diffusion of impurities into the memory cells 220 when the first gap fill patterns 250 are formed. The first gap fill patterns 250 may each include an insulating material such as oxide or nitride.

The second buffer patterns 260 may extend in the second direction II when viewed in a plan view, and may cover sidewalls of the memory cells 220 in the first direction I. For example, the second buffer patterns 260 may be located on sidewalls of the memory cells 220 that face each other in the first direction I. The second buffer patterns 260 might not be removed in the manufacturing process, and may remain on the sidewalls of the memory cells 220 to protect the memory cells 220. The second buffer patterns 260 may each include an insulating material such as nitride. For example, the second buffer patterns 260 may each include silicon nitride or the like.

The second liner patterns 270 may extend in the second direction II when viewed in a plan view, and may cover the sidewalls of the memory cells 220 in the first direction I. For example, the second liner patterns 270 may be located over the sidewalls of the memory cells 220 that face each other in the first direction I. Each of the second buffer patterns 260 may be located between a corresponding one of the second liner patterns 270 and a corresponding one of the memory cells 220. The second linear patterns 270 might not be removed in the manufacturing process, and may remain over the sidewalls of the memory cells 220 to protect the memory cells 220. The second linear patterns 270 may each include an insulating material such as nitride. For example, the second linear patterns 270 may each include silicon nitride or the like.

The second liner patterns 270 may each include a first portion 270P1 and a second portion 270P2. The first portion 270P1 and the second portion 270P2 may be formed in-situ, or may be formed by separate processes. Accordingly, the first portion 270P1 and the second portion 270P2 may be formed as one layer, or may be formed as separate layers.

The first portion 270P1 may have a fourth thickness, and the second portion 270P2 may have a fifth thickness. The fourth thickness and the fifth thickness may be substantially the same as or different from each other. For example, the fourth thickness and the fifth thickness may be substantially the same as each other. The second buffer patterns 260 may each have a sixth thickness. The sixth thickness may be substantially the same as or different from the fourth thickness and the fifth thickness. For example, the sixth thickness may be smaller than at least one of the fourth thickness or the fifth thickness.

The first portion 270P1 may include halide impurities at a first concentration, and the second portion 270P2 may include halide impurities at a second concentration that is lower than the first concentration. The second buffer patterns 260 may each include halide impurities at a third concentration that is lower than the first concentration and the second concentration. Here, the halide impurities may include at least one of iodine (I) or chlorine (Cl). The first portion 270P1 may have a first density, and the second portion 270P2 may have a second density that is higher than the first density.

In summary, the second buffer patterns 260 might not include the halide impurities, or may include the halide impurities at a lower concentration than the second liner patterns 270. In addition, since the concentration of the halide impurities in the second portion 270P2 of the second liner patterns 270 is lower than that of the halide impurities in the first portion 270P1 of the second liner patterns 270, the density of the second portion 270P2 may be higher than that of the first portion 270P1. Accordingly, the second liner patterns 270 and the second buffer patterns 260 may prevent or minimize damage to the memory cells 220 due to the diffusion of external impurities into the memory cell 220 when the second gap fill patterns 280 are formed or throughout the manufacturing process.

The second gap fill patterns 280 may be located between the memory cells 220 arranged in the first direction I. For example, each of the second gap fill patterns 280 may be located between two memory cells 220 adjacent to each other in the first direction I. The second gap fill patterns 280 may be located on the second liner patterns 270 in the first direction I. In a process of forming the second gap fill patterns 280, the second liner patterns 270 may be oxidized. However, since the second liner patterns 270 include nitride layers and the second portion 270P2 of each of the second liner patterns 270 has the high density, they may prevent or minimize the damage to the memory cells 220. The second gap fill patterns 280 may each include an insulating material such as oxide or nitride.

According to the structure described above with reference to FIGS. 2A to 2C, the first buffer patterns 230 and the first liner patterns 240 may cover the sidewalls of the memory cells 220 adjacent to each other in the second direction II, and the second buffer patterns 260 and the second liner patterns 270 may cover the sidewalls of the memory cells 220 adjacent to each other in the first direction I. Accordingly, it is possible to prevent or minimize the diffusion of the external impurities into the memory cells 220 in the process of forming the gap fill patterns 250 and 280 or throughout the manufacturing process.

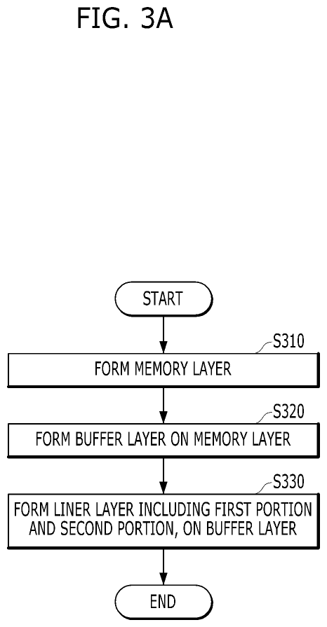

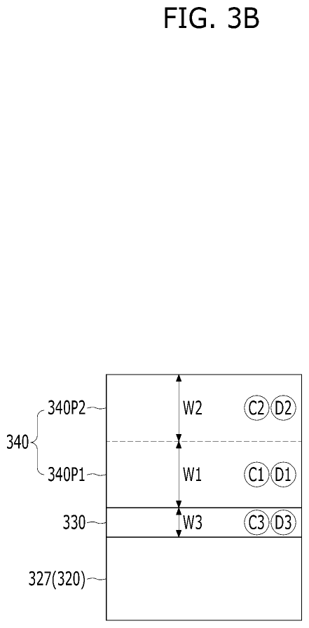

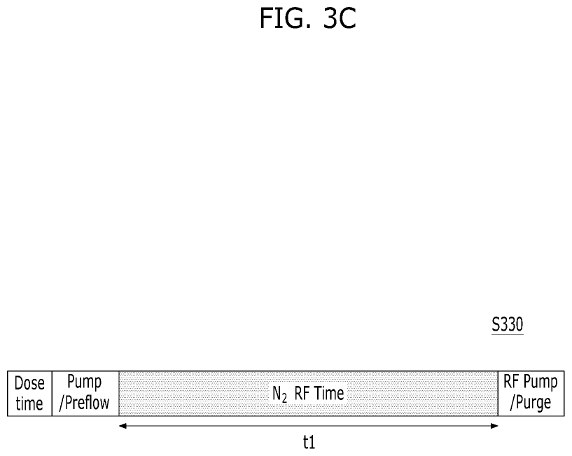

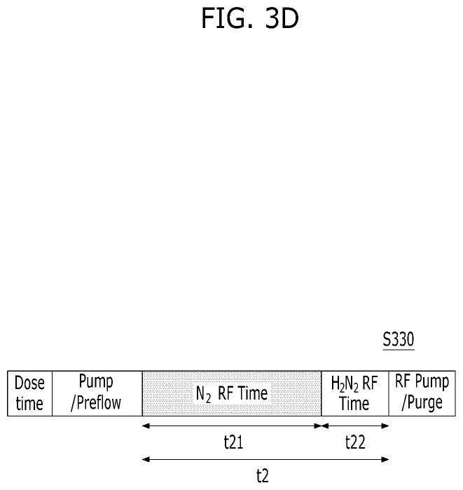

FIGS. 3A to 3D illustrate a manufacturing method of a semiconductor device in accordance with an embodiment. Hereinafter, the content overlapping with the previously described content will be omitted.

Referring to FIGS. 3A and 3B, a memory layer 320 may be formed (S310). The memory layer 320 may include a variable resistance layer 327. For example, the variable resistance layer 327 may be formed on a first electrode connected to a first conductive line. Alternatively, a switching layer and a second electrode may be formed on the first electrode connected to the first conductive line, and then the variable resistance layer 327 may be formed on the second electrode.

Subsequently, a buffer layer 330 may be formed on the variable resistance layer 327 (S320). The buffer layer 330 may be deposited by an atomic layer deposition (ALD) method. The buffer layer 330 may be formed through plasma treatment using a silicon source gas and a reaction gas including nitrogen. Here, the silicon source gas may include a silicon precursor that includes halogen elements. However, the silicon source gas is not limited thereto, and it may include a silicon precursor that does not include halogen elements. For example, the silicon source gas may be a SiH₄ gas, and the reaction gas may be an NH₃ gas. The following [Reaction Formula 1] represents a process of depositing the buffer layer 330.

3SiH₄+4NH₃->Si₃N₄+H₂ [Reaction Formula 1]

When the silicon source gas, which does not include the halogen elements, is used in the process of depositing the buffer layer 330, halide impurities might not exist in the buffer layer 330. Accordingly, when the buffer layer 330 is formed, the diffusion of the halide impurities into the memory layer 320 may be prevented or minimized.

Subsequently, a liner layer 340 may be formed on the buffer layer 330 (S330). For example, the liner layer 340 may be formed by forming a first portion 340P1 on the buffer layer 330 and then forming a second portion 340P2 on the first portion 340P1. The first portion 340P1 and the second portion 340P2 may be deposited by an ALD method. The first portion 340P1 and the second portion 340P2 may be formed by separate processes or may be formed in-situ. However, embodiments are not limited thereto. In another embodiment, the buffer layer 330, the first portion 340P1, and the second portion 340P2 may be formed in-situ.

Referring to FIG. 3C, the first portion 340P1 may be deposited through a plurality of steps. For example, the plurality of steps may include at least one of a dose step, a pump/preflow step, a plasma treatment step, or a purge step. Here, the dose step and the pump/preflow step may refer to steps of supplying a silicon source gas and a reaction gas. For example, the silicon source gas may be a SiH₂I₂ gas (diiodosilane, DIS), and the reaction gas may be at least one of an N₂ gas or an H₂N₂ gas. The plasma treatment step may refer to a step of performing plasma treatment by supplying a treatment gas and then applying radio frequency (RF) power. Here, the treatment gas may be at least one of an N₂ gas or an H₂N₂ gas. The purge step may refer to a step of removing remaining reactants after the plasma treatment. A cycle of the plurality of steps described above may be repeated one or more times.

More specifically, the dose step may be performed for 0.5 to 4 seconds in order to form the first portion 340P1. For example, the dose step may be performed for approximately 2 seconds. Subsequently, the pump step may be performed for 1 to 3 seconds, and the preflow step may be performed for 0.5 to 3 seconds. For example, the pump step may be performed for approximately 2 seconds, and the preflow step may be performed for approximately 1 second. Subsequently, the plasma treatment step using an N₂ gas may be performed for 5 to 60 seconds. For example, the plasma treatment step may be performed for approximately 30 seconds. Subsequently, the purge step may be performed for 0.1 to 5 seconds to remove the remaining reactants. For example, the purge step may be performed for approximately 3 seconds.

During one cycle, the first portion 340P1 may be deposited to a thickness ranging from 0.1 to 1 Å. For example, during one cycle, the first portion 340P1 may be deposited to a thickness of approximately 0.45 Å. Through multiple repeated cycles, the first portion 340P1 may be formed to a first thickness W1, which may be approximately 4.5 Å.

The following [Reaction Formula 2] represents a process of depositing the first portion 340P1.

4SiH₂I₂(DIS)+2N₂->Si₃N₄+6HI+I₂+SiHₓI_{y} [Reaction Formula 2]

The first portion 340P1 may be formed through the plasma treatment using the silicon source gas and the reaction gas including nitrogen. Here, the silicon source gas may include halogen elements.

For example, the silicon source gas may be a SiH₂I₂ (DIS) gas, and the reaction gas may be an N₂ gas. Because the silicon precursor with the halogen elements is used in the process of depositing the first portion 340P1, halide impurities may be present at a first concentration C1 in the first portion 340P1. Here, the halide impurities may include at least one of chlorine (Cl) or iodine (I).

The second portion 340P2 may be deposited on the first portion 340P1. Referring to FIG. 3D, the second portion 340P2 may be deposited through at least one of a dose step, a pump/preflow step, a plasma treatment step, or a purge step. The second portion 340P2 may be deposited by performing multiple cycles of the above steps.

More specifically, the dose step may be performed for 0.5 to 4 seconds in order to form the second portion 340P2. For example, the dose step may be performed for approximately 2 seconds. Subsequently, the pump step may be performed for 1 to 3 seconds, and the preflow step may be performed for 0.5 to 3 seconds. For example, the pump step may be performed for approximately 2 seconds, and the preflow step may be performed for approximately 1 second. Here, a silicon source gas including halogen elements may be supplied, and a reaction gas including nitrogen may be supplied. For example, the silicon source gas may include SiH₂I₂ as a silicon precursor that includes halogen elements, and the reaction gas may include at least one of an N₂ gas or an H₂N₂ gas. Subsequently, the plasma treatment step using an N₂ gas and an H₂N₂ gas may be performed for 5 to 60 seconds. For example, the plasma treatment step may be performed for approximately 11 seconds. The plasma treatment step may include a plurality of steps. For example, primarily, a first plasma treatment step using the N₂ gas may be performed for 5 to 30 seconds. For example, the first plasma treatment step using the N₂ gas may be performed for approximately 8 seconds. Secondarily, a second plasma treatment step using the H₂N₂ gas may be performed for 1 to 15 seconds. For example, the second plasma treatment step using the H₂N₂ gas may be performed for approximately 3 seconds. Subsequently, the purge step may be performed for 0.1 to 3 seconds to remove remaining reactants. For example, the purge step may be performed for approximately 0.25 seconds.

During one cycle of the above steps, the second portion 340P2 may be deposited to a thickness ranging from 0.5 to 1 Å. Through the multiple cycles, the second portion 340P2 may be formed to a second thickness W2, which may be approximately 5.2 Å.

In addition, a relatively low plasma density may be accumulated in the process of forming the second portion 340P2. A plasma density used when forming the second portion 340P2 may be lower than a plasma density used when forming the first portion 340P1. Accordingly, when forming the liner layer 340 using the plasma treatment with only the N₂ gas, the memory layer 320 may be exposed to the plasma for a relatively long time, thereby causing the memory layer 320 to be leaned. However, when performing the plasma treatment with the N₂ and H₂N₂ gases, the memory layer 320 may be exposed to plasma for a relatively short time, thereby reducing the leaning of the memory.

The following [Reaction Formula 3] represents the process of depositing the second portion 340P2.

4SiH₂I₂(DIS)+2N₂+H₂N₂->Si₃N₄+6HI+I₂+SiHₓI_{y}+HCl [Reaction Formula 3]

The second portion 340P2 may be formed through the plasma treatment using the silicon source gas and the reaction gas including nitrogen and hydrogen. Here, the silicon source gas may include halogen elements. For example, the silicon source gas may be a SiH₂I₂ (DIS) gas, and the reaction gas may include an N₂ gas and an H₂N₂ gas. Because the silicon precursor including the halogen elements is used in the process of depositing the second portion 340P2, halide impurities may be present at a second concentration C2 in the second portion 340P2. The second concentration C2 may be lower than the first concentration C1. This occurs because a reaction product formed between the halogen elements (Cl or I) in the silicon source gas and the H₂N₂ gas may volatilize. For example, some of the halogen elements included in the silicon source gas may volatilize as HI or HCl.

In the process of forming the second portion 340P2, relatively

more halogen elements may volatilize compared to the first portion 340P1. As a result, the second portion 340P2 may include the halide impurities at the second concentration C2, which is lower than the first concentration C1. That is, the second portion 340P2 includes less halide impurities than the first portion 340P1. Accordingly, the second portion 340P2 may have a second density D2, which is higher than a first density D1 of the first portion 340P1.

Referring to FIGS. 3C and 3D, a second reaction time for forming the second portion 340P2 may be shorter than a first reaction time for forming the first portion 340P1. Here, the reaction time may refer to one cycle for forming each of the first portion 340P1 and the second portion 340P2. In addition, a speed at which the second portion 340P2 is formed may be higher than a speed at which the first portion 340P1 is formed. For example, the second portion 340P2 may be formed at a higher speed than the first portion 340P1.

Therefore, the memory layer 320 may be less exposed to plasma when the second portion 340P2 is formed than when the first portion 340P1 is formed. Accordingly, the leaning of the memory layer 320 due to the plasma treatment may be reduced when forming the second portion 340P2 compared to the formation of the first portion 340P1.

In addition, the thicknesses of the first portion 340P1 and the second portion 340P2 may be substantially the same as or different from each other. For example, the first thickness W1 of the first portion 340P1 and the second thickness W2 of the second portion 340P2 may be substantially the same as each other. A speed at which the second portion 340P2 is deposited may be higher than a speed at which the first portion 340P1 is deposited. Therefore, in order to deposit the second portion 340P2 so that the second thickness W2 is substantially the same as the first thickness W1, the second portion 340P2 may be formed by performing fewer cycles than those used to form the first portion 340P1. Alternatively, when the thicknesses of the first portion 340P1 and the second portion 340P2 are different from each other, the first portion 340P1 may have a thickness of approximately 4.5 A, and the second portion 340P2 may have a thickness of approximately 5.2 Å.

The memory layer 320 may be damaged in the process of performing the plasma treatment. For example, the memory layer 320 may be leaned in the process of performing the plasma treatment in order to form the first portion 340P1 and the second portion 340P2. Accordingly, a time during which the memory layer 320 is exposed to the plasma needs to be reduced. For example, a relatively high plasma density may be accumulated in a process of performing ten cycles for forming the first portion 340P1. A relatively low plasma density may be accumulated in a process of performing six cycles for forming the second portion 340P2. Accordingly, when forming the liner layer 340 as a single layer using only the plasma treatment with the N₂ gas, a greater number of cycles is required, so that a higher plasma density may be accumulated. On the other hand, when forming the liner layer 340, which includes the first portion 340P1 and the second portion 340P2, using the plasma treatment with the N₂ gas and the H₂N₂ gas, fewer cycles are required. This leads to a relatively lower plasma density accumulation, thereby reducing damage to the memory layer 320.

According to the inventive manufacturing method described above, the liner layer 340 may be divided into the first portion 340P1 and the second portion 340P2. The first portion 340P1 may be formed through the first plasma treatment using the N₂ gas, and the second portion 340P2 may be formed through the second plasma treatment using the N₂ gas and the H₂N₂ gas. When the second portion 340P2 is formed, the halogen elements included in the SiH₂I₂ precursor may volatilize, so that the concentration of halide impurities in the liner layer 340 may be reduced. Accordingly, the density of the liner layer 340 may be increased, and thus the diffusion of external impurities into the memory layer 320 in a subsequent process may be prevented or minimized by the liner layer 340.

In addition, since a relatively short time may be required when forming the second portion 340P2 using the plasma treatment with the N₂ gas and the H₂N₂ gas, a time during which the memory layer 320 is exposed to the plasma may be reduced. Accordingly, it is possible to prevent or minimize the leaning of the memory layer 320 and the damage to the memory layer 320 due to the plasma treatment.

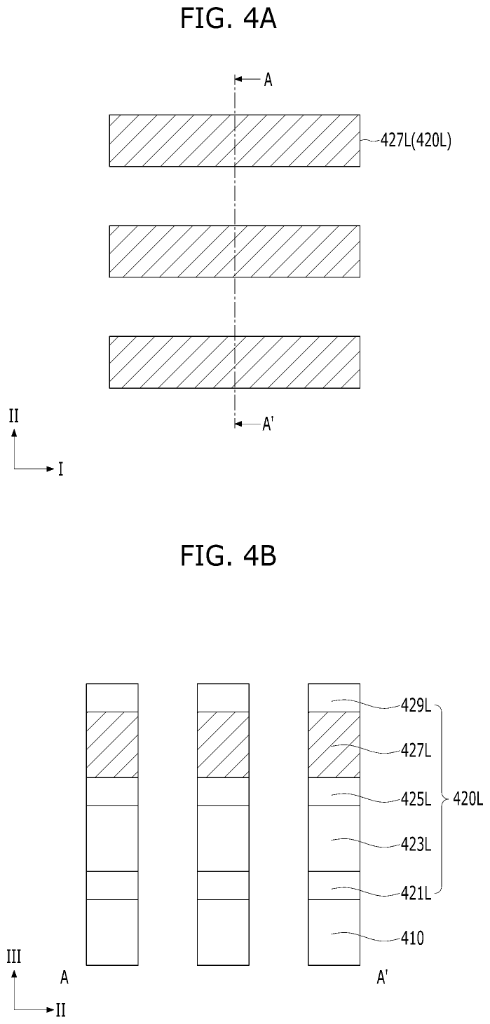

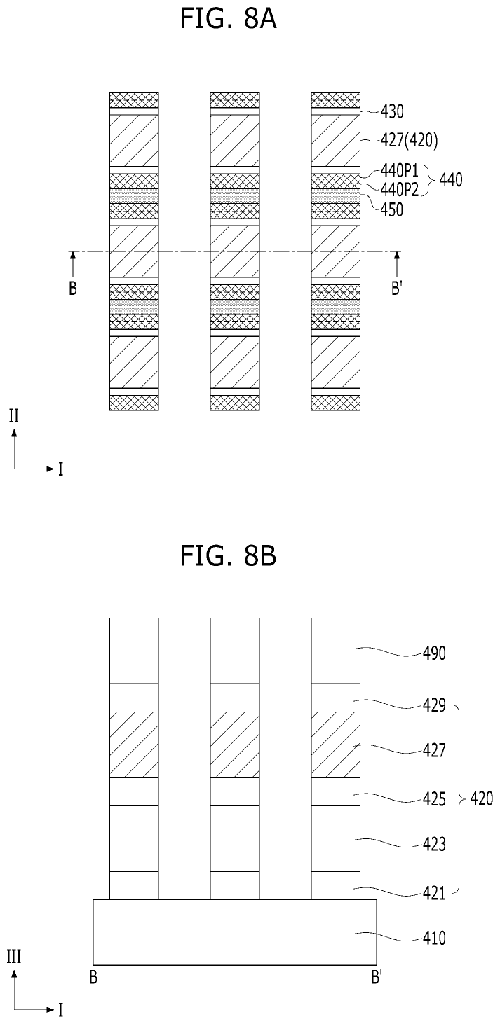

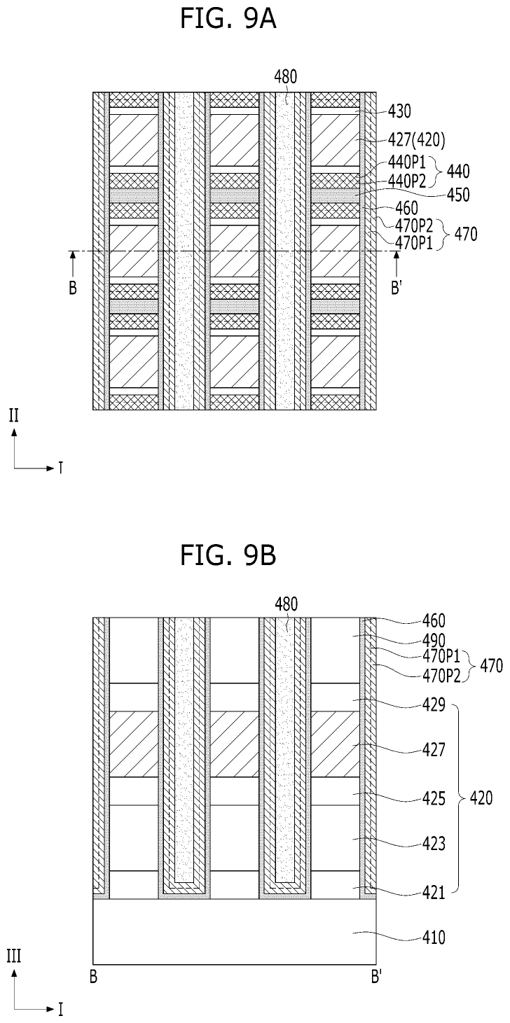

FIGS. 4A to 9B illustrate a manufacturing method of a semiconductor device in accordance with an embodiment. FIGS. 4A, 5A, 6A, 7A, 8A, and 9A may be plan views, FIGS. 4B, 5B, 6B, and 7B may be cross-sectional views taken along lines A-A′ of FIGS. 4A, 5A, 6A, and 7A, respectively, and FIGS. 8B and 9B may be cross-sectional views taken along lines B-B′ of FIGS. 8A and 9A, respectively. Hereinafter, the content overlapping with the previously described content will be omitted.

Referring to FIGS. 4A and 4B, first conductive lines 410 extending in a first direction I may be formed. Memory lines 420L extending in the first direction I and each including a variable resistance line 427L may be formed on the first conductive lines 410. Each of the first conductive lines 410 and the memory lines 420L may be spaced apart from each other in a second direction II intersecting the first direction I.

To form the first conductive lines 410 and the memory lines 420L, a first conductive layer may be formed over a substrate. Subsequently, a memory layer may be formed on the first conductive layer. The memory layer may be formed by sequentially stacking a first electrode layer, a switching layer, a second electrode layer, a variable resistance layer, and a third electrode layer in a third direction III intersecting the first direction I and the second direction II. Here, the third direction III may be intersecting to a plane defined by the first direction I and the second direction II.

Subsequently, the memory lines 420L and the first conductive lines 410 may be formed by patterning the memory layer and the first conductive layer through an etching process. The memory line 420L may include a first electrode line 421L, a switching line 423L, a second electrode line 425L, a variable resistance line 427L, and a third electrode line 429L. The first conductive line 410 may be a word line or a bit line. The first conductive line 410 may include a conductive material such as tungsten. The first electrode line 421L, the second electrode line 425L, and the third electrode line 429L may each include metal, metal nitride, carbon, carbon nitride, or the like. At least one of the switching line 423L or the variable resistance line 427L may include a chalcogenide material.

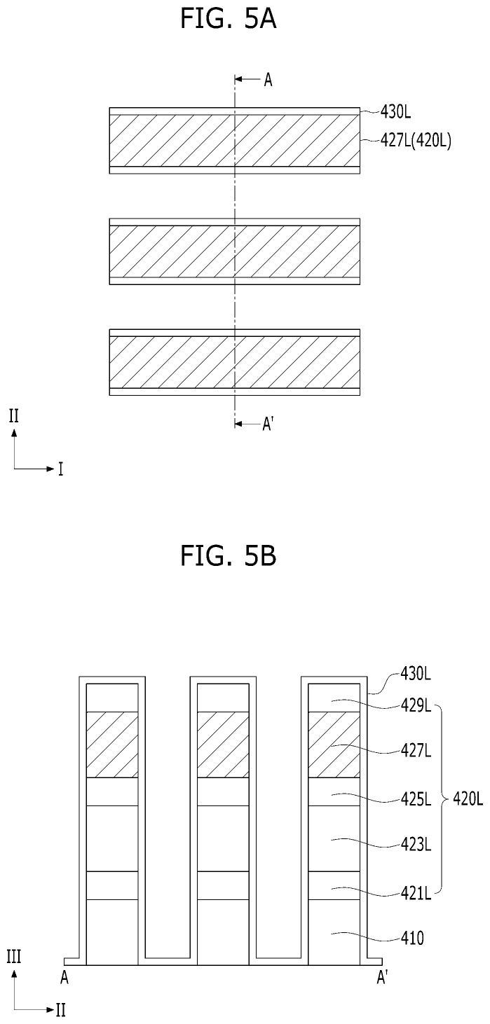

Referring to FIGS. 5A and 5B, a first buffer layer 430L may be formed. The first buffer layer 430L may be formed along profiles of the first conductive lines 410 and the memory lines 420L, which extend in the first direction I. The first buffer layer 430L may be deposited by an atomic layer deposition (ALD) method. For example, the first buffer layer 430L may be formed using a SiH₄ precursor, which does not include halogen elements, and an NH₃ gas. The first buffer layer 430L may include an insulating material such as nitride. For example, the first buffer layer 430L may include silicon nitride or the like.

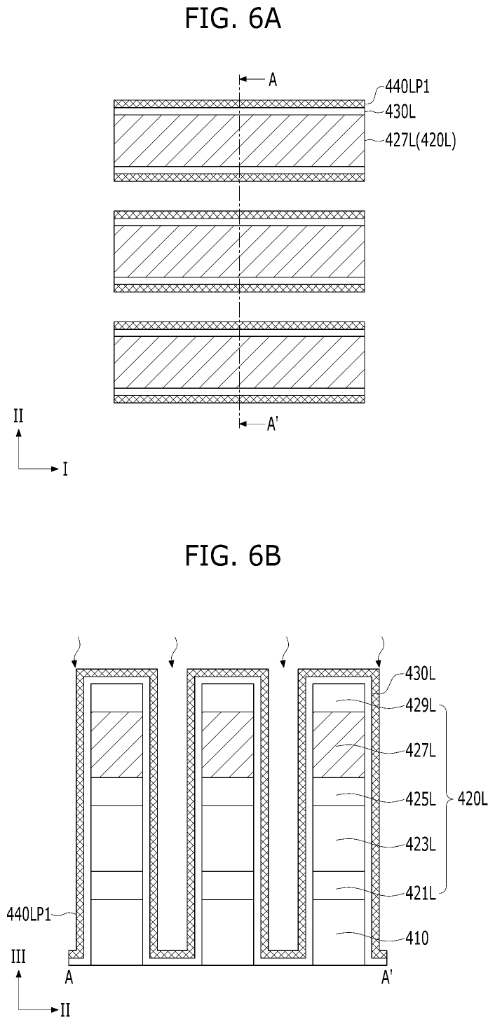

Referring to FIGS. 6A and 6B, a first portion 440LP1 constituting a first liner layer may be formed on the first buffer layer 430L. The first portion 440LP1 may be deposited by an ALD method. Referring back to FIGS. 3A to 3D, the first portion 440LP1 may be deposited through the plasma treatment using the SiH₂I₂ precursor, which includes halogen elements, and the N₂ gas. As a first reaction time for forming the first portion 440LP1, a relatively long time may be required. In this case, the memory line 420L may be exposed to plasma for a relatively long time, and thus it may be damaged. Accordingly, in a subsequent process, a second portion 440LP2 of the first liner layer should be formed quickly to minimize or prevent the damage to the memory line 420L.

In the process of depositing the first portion 440LP1, halide impurities may be generated. For example, in the process of depositing the first portion 440LP1, halide impurities such as iodine (I) or chlorine (Cl) may be generated. The first portion 440LP1 may include the halide impurities at a first concentration. The first portion 440LP1 may have a first density.

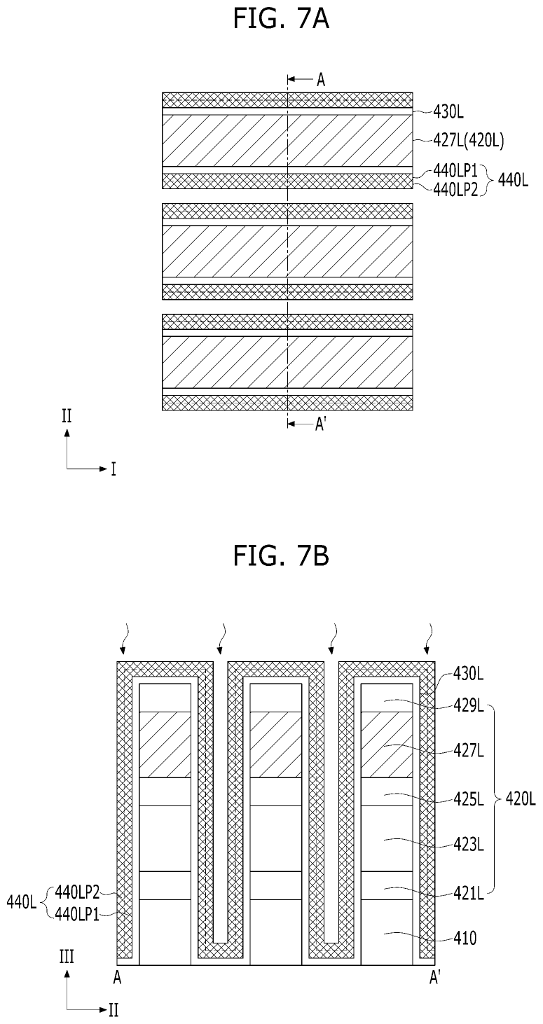

Referring to FIGS. 7A and 7B, the second portion 440LP2 may be formed on the first portion 440LP1. Consequently, a first liner layer 440L including the first portion 440LP1 and the second portion 440LP2 may be formed. The second portion 440LP2 may be deposited by an ALD method. Referring back to FIGS. 3A to 3D, the second portion 440LP2 may be deposited through the plasma treatment using the SiH₂I₂ precursor, which includes halogen elements, an N₂ gas, and an H₂N₂ gas. As a second reaction time for forming the second portion 440LP2, a time that is shorter than the first reaction time may be required. In this case, the memory line 420L may be exposed to plasma for a relatively short time, and thus damage to the memory line 420L may be reduced.

In the process of depositing the second portion 440LP2, halide impurities may be generated. For example, in the process of depositing the second portion 440LP2, halide impurities such as iodine (I) or chlorine (Cl) may be generated. When the plasma treatment using the H₂N₂ gas is performed, iodine (I) in the SiH₂I₂ precursor may react with the H₂N₂ gas and volatilize as HI. Accordingly, the second portion 440LP2 may include halide impurities at a second concentration that is lower than the first concentration. Therefore, the second portion 440LP2 may have a second density that is higher than the first density.

In other words, by forming the second portion 440LP2 through the plasma treatment using the H₂N₂ gas, the memory lines 420L may be exposed to plasma for a relatively short time and an average density in the first liner layer 440L may increase. As a result, the damage to the memory lines 420L may be prevented or minimized.

In FIGS. 6A to 7B, the first portion 440LP1 and the second portion 440LP2 of the first liner layer 440L have been described with reference to separate drawings for convenience of explanation, but the first portion 440LP1 and the second portion 440LP2 may be formed in-situ. When the second portion 440LP2 is formed, the halide impurities may be formed at a relatively low concentration through the plasma treatment using the H₂N₂ gas. Therefore, the halide impurities may be formed at a low concentration on average in the first liner layer 440L. Accordingly, an average density of the first liner layer 440L may increase.

Referring to FIGS. 8A and 8B, a first gap fill layer may be formed on the first liner layer 440L to fill the remaining spaces between memory lines 420L in the second direction II. In a process of forming the first gap fill layer, a portion of the first liner layer 440L may be oxidized. However, the first liner layer 440L may include the halide impurities at the relatively low concentration and have a high average density, and thus, the first liner layer 440L and the memory lines 420L might not be damaged in the process of forming the first gap fill layer. Subsequently, upper surfaces of the memory lines 420L may be exposed by performing planarization on the first gap fill layer, the first liner layer 440L, and the first buffer layer 430L.

Subsequently, second conductive lines 490 extending in the second direction II and memory cells 420 arranged in the first direction I and the second direction II may be formed. Here, the second conductive lines 490 may be formed to be spaced apart from each other in the first direction I.

To form the second conductive lines 490, a second conductive layer may be formed on the memory lines 420L and the planarized first gap fill layer, first liner layer 440L, and first buffer layer 430L. Subsequently, the second conductive lines 490 may be formed by patterning the second conductive layer through an etching process. Subsequently, the memory cells 420 may be formed by etching the memory lines 420L, using the second conductive lines 490 as etching masks, until upper surfaces of the first conductive lines 410 are exposed. As a result, each of the memory cells 420 may include a first electrode pattern 421, a switching pattern 423, a second electrode pattern 425, a variable resistance pattern 427, and a third electrode pattern 429. The first electrode pattern 421 may be a lower electrode, the second electrode pattern 425 may be an intermediate electrode, and the third electrode pattern 429 may be an upper electrode.

For reference, in the process of forming the second conductive lines 490 and the memory cells 420, the first gap fill layer may be divided into first gap fill patterns 450 that are arranged in the first direction I, the first liner layer 440L may be divided into first liner patterns 440 that are arranged in the first direction I, and the first buffer layer 430L may be divided into first buffer patterns 430 that are arranged in the first direction I. Here, the first portion 440LP1 of the first liner layer 440L may be a first portion 440P1 of the first liner pattern 440, and the second portion 440LP2 of the first liner layer 440L may be a second portion 440P2 of the first liner pattern 440. The second conductive lines 490 may each be a word line or a

bit line. For example, when the first conductive line 410 is a word line, the second conductive line 490 may be a bit line. Alternatively, when the first conductive line 410 is a bit line, the second conductive line 490 may be a word line. The second conductive line 490 may include a conductive material. For example, the second conductive line 490 may include a metal material such as tungsten.

Referring to FIGS. 9A and 9B, second buffer patterns 460, second liner patterns 470, and second gap fill patterns 480 may be formed. The second buffer patterns 460 may be formed by a method similar to the method of forming the first buffer layer 430L. The second liner patterns 470 may be formed by a method similar to the method of forming the second liner layer 440L. Therefore, each of the second liner patterns 470 includes a first portion 470P1 and a second portion 470P2. For example, the first portion 470P1 of the second liner patterns 470 may be formed through plasma treatment using a SiH₂I₂ precursor, which includes halogen elements, and an N₂ gas. The second portion 470P2 of the second liner patterns 470 may be formed through plasma treatment using a SiH₂I₂ precursor, which includes halogen elements, an N₂ gas, and an H₂N₂ gas. The second gap fill patterns 480 may be formed by a method similar to the method of forming the first gap fill layer 450.

Consequently, the first buffer patterns 430 and the first liner patterns 440 may be formed on sidewalls of memory cells 420 adjacent to each other in the second direction II, and the second buffer patterns 460 and the second liner patterns 470 may be formed on sidewalls of memory cells 420 adjacent to each other in the first direction I.

According to the manufacturing method described above, the second portions 440P2 and 470P2 may include the halide impurities at a relatively low concentration, and thus may have a relatively high density. Accordingly, damage to the memory cells 420 in the manufacturing process may be prevented or minimized.

In addition, the second portions 440P2 and 470P2 may be formed for a relatively short time, and thus, the memory cells 420 may be exposed to plasma for a relatively short time. Accordingly, damage to the memory cells 420 may be prevented or minimized.

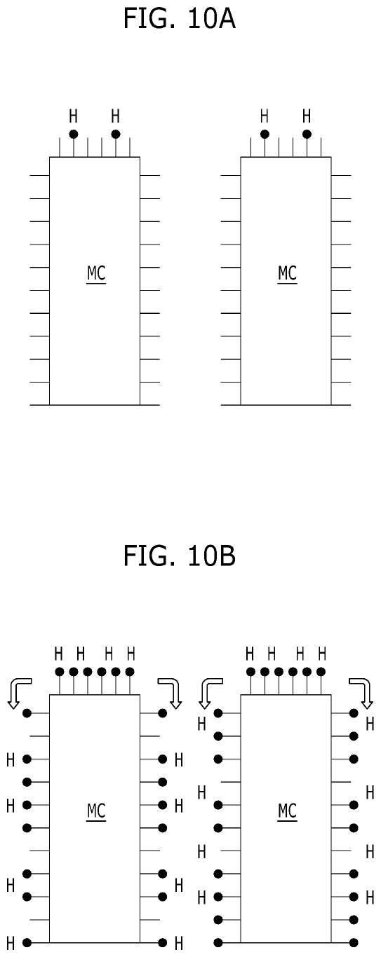

FIGS. 10A and 10B illustrate an effect of a manufacturing method of a semiconductor device in accordance with an embodiment. Hereinafter, the content overlapping with the previously described content will be omitted.

FIGS. 10A and 10B are schematic diagrams illustrating the distribution of hydrogen (H) in a process of forming liner layers (not illustrated) on memory cells MC. Referring to FIG. 10A, in a process of forming liner layers through plasma treatment using a SiH₂I₂ precursor, which includes halogen elements, and an N₂ gas, hydrogen (H) may be concentrated on upper surfaces of the memory cells MC to form active sites. Here, hydrogen (H) may serve as a catalyst increasing a reaction rate. For example, hydrogen (H) and halogen elements (I or Cl) of a silicon source gas may be adsorbed and react with each other. Accordingly, when hydrogen (H) is concentrated and formed only on the upper surfaces of the memory cells MC to form the active sites, a speed at which the liner layers are deposited on side surfaces of the memory cells MC may be relatively low.

Referring to FIG. 10B, in a process of forming liner layers through plasma treatment using a SiH₂I₂ precursor, which includes halogen elements, an N₂ gas, and an H₂N₂ gas, hydrogen (H) may be distributed on the side surfaces as well as the upper surfaces of the memory cells MC to form active sites. Here, hydrogen (H) of the

H₂N₂ gas and the halogen elements (I or Cl) may be adsorbed and react with each other, such that the liner layers may be deposited at a speed relatively higher than that in the case of FIG. 10A.

As described above, the liner layers may be deposited on the memory cells MC at a relatively higher speed when the liner layers are deposited on the memory cells MC through the plasma treatment using both the N₂ gas and the H₂N₂ gas than when the liner layers are deposited on the memory cells MC through the plasma treatment using only the N₂ gas. In addition, when the liner layers are deposited on the memory cells MC through the plasma treatment using both the N₂ gas and the H₂N₂ gas, hydrogen (H) of the H₂N₂ gas may react with the halogen elements (I or Cl), thereby reducing a concentration of the halide impurities in the liner layers and thus increasing a density of the liner layers.

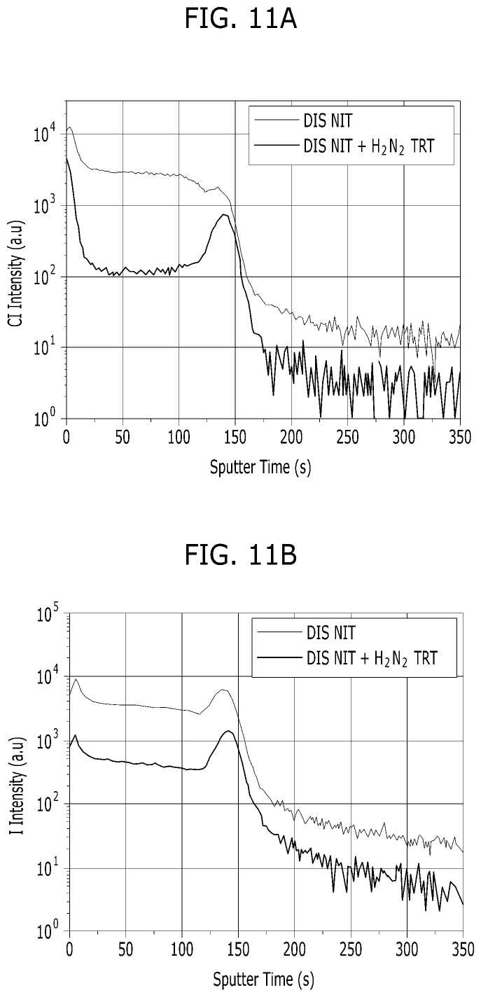

FIGS. 11A and 11B illustrates an effect of a manufacturing method of a semiconductor device in accordance with an embodiment. Hereinafter, the content overlapping with the previously described content will be omitted.

FIGS. 11A and 11B are graphs for describing a difference in

concentration of halide impurities (Cl and I) in liner layers (not illustrated) when the liner layers are formed through plasma treatment using only an N₂ gas and when the liner layers are formed through plasma treatment using an N₂ gas and an H₂N₂ gas. Referring to FIGS. 11A and 11B, it can be seen that

concentrations of the halide impurities (I and Cl) in the liner layers are lower when the plasma treatment using the N₂ gas and the H₂N₂ gas is performed on a SiH₂I₂ precursor (DIS) including halogen elements (I and Cl) in order to form the liner layers than when the plasma treatment using the N₂ gas is performed on the SiH₂I₂ precursor (DIS).

Observations over about 50 seconds have yielded certain insights into the effects of plasma treatment on the halide impurities (I and Cl) in the liner layers. Specifically, when the plasma treatment is performed using only the N₂ gas, there is no notable change in the concentrations of these impurities. In contrast, when the plasma treatment is performed using both the N₂ gas and the H₂N₂ gas, the concentrations of the halide impurities (I and Cl) in the liner layers rapidly decrease.

In addition, based on observations over about 150 seconds, it can be confirmed that the concentrations of the halide impurities (I and Cl) in the liner layers are lower when the plasma treatment is performed using both the N₂ gas and the H₂N₂ gas, compared to using only the N₂ gas.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
a first conductive line extending in a first direction;
a second conductive line extending in a second direction intersecting the first direction;
a memory cell located between the first conductive line and the second conductive line in a third direction that intersects the first and second directions; and
a liner pattern located over a sidewall of the memory cell and including a first portion and a second portion, the first portion including halide impurities at a first concentration, the second portion including halide impurities at a second concentration that is lower than the first concentration.

2. The semiconductor device of claim 1, wherein the memory cell includes a variable resistance layer.

3. The semiconductor device of claim 1, wherein the first portion is located between the memory cell and the second portion.

4. The semiconductor device of claim 1, wherein the halide impurities include at least one of iodine (I) or chlorine (Cl).

5. The semiconductor device of claim 1, wherein the liner pattern includes nitride.

6. The semiconductor device of claim 1, further comprising a buffer pattern located between the memory cell and the liner pattern and including halide impurities at a third concentration that is lower than the second concentration.

7. The semiconductor device of claim 6, wherein the buffer pattern includes nitride.

8. The semiconductor device of claim 1, wherein the first portion has a first density of a nitride layer, and the second portion has a second density of the nitride layer that is higher than the first density of the nitride layer.

9. The semiconductor device of claim 1, wherein the first portion has a first thickness, and the second portion has a second thickness that is substantially the same as the first thickness.

10. The semiconductor device of claim 9, further comprising a buffer pattern located between the memory cell and the liner pattern and having a third thickness that is smaller than the first thickness and the second thickness.

11. The semiconductor device of claim 1, further comprising a gap fill pattern located on the liner pattern.

12. A manufacturing method of a semiconductor device, the manufacturing method comprising:
forming a variable resistance layer;
forming a buffer layer on a sidewall of the variable resistance layer; and
forming a liner layer on the buffer layer, the liner layer including a first portion and a second portion, the first portion including halide impurities at a first concentration, the second portion including halide impurities at a second concentration that is lower than the first concentration.

13. The manufacturing method of claim 12, wherein in the forming of the first portion of the liner layer, the first portion is deposited on the buffer layer by performing plasma treatment using a silicon precursor and an N₂ gas, the silicon precursor including halogen elements.

14. The manufacturing method of claim 13, wherein in the forming of the second portion of the liner layer, the second portion is deposited on the first portion by performing plasma treatment using the silicon precursor, the N₂ gas, and an H₂N₂ gas.

15. The manufacturing method of claim 14, wherein in the forming of the second portion of the liner layer, a product formed by a reaction between the H₂N₂ gas and the halogen elements volatilizes.

16. The manufacturing method of claim 12, wherein in the forming of the buffer layer, the buffer layer is deposited on the sidewall of the variable resistance layer by performing plasma treatment using a silicon precursor, which does not include halogen elements, and an NH₃ gas.

17. The manufacturing method of claim 12, wherein the buffer layer, the first portion, and the second portion each include nitride.

18. The manufacturing method of claim 12, wherein the buffer layer, the first portion, and the second portion are deposited by an atomic layer deposition (ALD) method.

19. The manufacturing method of claim 18, wherein the buffer layer, the first portion, and the second portion are deposited in-situ.

20. The manufacturing method of claim 12, wherein a speed at which the second portion is formed is higher than a speed at which the first portion is formed.

21. The manufacturing method of claim 12, wherein a second reaction time for forming the second portion is shorter than a first reaction time for forming the first portion.

22. The manufacturing method of claim 12, wherein a plasma density used when forming the second portion is lower than a plasma density used when forming the first portion.

23. The manufacturing method of claim 12, further comprising forming a gap fill layer on the liner layer.
